(19) United States
(12) Patent Application Publication
(10) Pub. No.: US 2007/0111474 A1
(43) Pub. Date: May 17, 2007

(54) Treating a SiGe layer for selective etching

(76) Inventors: Cecile Delattre, Saint Hilaire Du Touvet (FR); Nicolas Daval, Grenoble (FR)

Correspondence Address: WINSTON & STRAWN LLP;PATENT DEPARTMENT, 1700 K STREET, N.W., WASHINGTON, DC, 20006, US

(21) Appl. No.: 11/356,927

(22) Filed: Feb. 16, 2006

(30) Foreign Application Priority Data
Nov. 16, 2005 (FR) FR 0511600

(51) Int. Cl. H01L 21/30; H01L 21/311; H01L 21/31

(52) U.S. Cl. 438/459; 438/694; 438/767

(57) ABSTRACT

The invention relates to a method of lifting a layer of silicon-germanium of formula Si₁₋ₓGeₓ (0≦x≦1) disposed on a layer of strained silicon. The layer of silicon-germanium is intended to be lifted by selective chemical etching to expose the strained silicon layer. Prior to selective etching step, the method includes a step of oxidation of the layer of silicon-germanium to form a superficial layer of silicon oxide and an enriched lower layer having a concentration (x) of germanium which is greater than that of the layer of silicon-germanium. The layer of silicon oxide is then eliminated by a deoxidation step.

### BACKGROUND

The present invention relates to the fabrication of wafers, in particular those of the strained silicon on insulator (sSOI) type.

Several techniques exist for producing such wafers. One of the best current techniques for the fabrication of sSOI type wafers is that of producing an active layer of strained silicon (abbreviated to sSi) using SMART-CUT® technology to produce the desired heterostructure. An example of the use of SMART-CUT® technology applied to the production of SOI wafers has been described in United States patent U.S. Pat. No. 5,374,564 or in the article by A. J. Auberton-Hervé et al entitled “Why can SMART-CUT® change the future of microelectronics?”, Int. Journal of High Speed Electronics and Systems, Vol. 10, No. 1, 2000, p. 131-146. Examples of the use of SMART-CUT® technology applied to the specific production of sSOI type wafers are described in United States patent application U.S. Pat. No. 6,953,736 and International patent application WO-A-2004/006311.

The production of sSOI type wafers involving SMART-CUT® technology initially comprises fabricating a “donor” substrate formed by a silicon support substrate onto which a relaxed silicon-germanium (SiGe) layer is formed via a SiGe buffer layer. A layer of strained silicon is then formed on the relaxed SiGe layer, for example by epitaxial growth. The concentration of Ge in the relaxed layer is typically of the order of 20%, but it may vary depending on the amount of strain desired in the silicon film.

Once the strained silicon layer has been formed using the SMART-CUT® technology, atomic species are implanted in the relaxed SiGe layer in an implantation zone and the face of the strained silicon layer is brought into intimate contact with a “receiver” substrate. The SiGe layer is then split at the implantation zone to transfer the portion located between the surface which undergoes implantation and the implantation zone (i.e., the layer of sSi and a portion of the relaxed SiGe layer) onto the receiver substrate.

An sSOI structure is thereby obtained with a strained silicon layer on one face of the support substrate. After splitting and transfer, the remainder of the SiGe subsisting above the strained silicon layer is then lifted off. Typically, the lifting is carried out by selective etching. The term “selective etching” as used here means the chemical attack method which can selectively eliminate the upper layer of SiGe without attacking the next layer of strained silicon, termed the stop layer for this reason, by adjusting the composition of the chemical solution and, as a result, adjusting the etching rates between the SiGe and the silicon.

Clearly, the more the natures of the layers differ, the greater the selectivity.

Heat treatments which are used during formation on the donor substrate and/or during transfer of layers of strained silicon and SiGe contribute to the diffusion of elements of germanium into the strained silicon layer. In fact, the SMART-CUT® technology imposes heat treatments, such as densification of the deposited oxide, the “detaching” or “splitting” heat treatment, any post-detachment or post-splitting heat treatments which precede etching (e.g., pre-stabilization strengthening of the bonding interface at about 800° C. for several hours). These heat treatments are important, and they cannot be restricted for the purpose of avoiding diffusion of elements of germanium.

As a result, the transition from a SiGe zone to a silicon zone (for example a change in the concentration of Ge from 20% to 0%) is not abrupt but extends over a certain thickness (about 50 angstroms (Å) to 100 Å, for 20% Ge) by diffusion of germanium into the subjacent strained silicon layer. As shown in FIG. 4, which shows the variation in the germanium concentration in the thickness of the transferred portion (i.e., the strained silicon layer and the portion of the SiGe layer above implantation), this progressive transition occurs over a certain thickness between the layer of SiGe and the layer of strained silicon may be defined by a transition layer or zone which extends between the SiGe and sSi layers.

This transition layer (i.e., one that has no abrupt interface between the SiGe and sSi layers) generally contains very little germanium. Further, the concentration of germanium in that layer decreases progressively as the strained silicon layer is approached. Further, selective etching of germanium at that layer must be prolonged for a long period in order to remove all of the germanium that is present. This excessive prolongation of etching leads to the formation of a rough post-etch surface, or even to the formation of HF defects, and lifting off or removing the whole transitional zone containing germanium leads to over-etching of the layer of strained silicon. This over-etching is particularly pronounced at defects or zones of weakness (dislocations, crystal defects, impurities or contaminants, irregularities in thickness) in the transferred layer (“HF” defects are defects in the active semiconductive layer of the sSOI structure, here the sSi layer, which extend from the surface of the layer to the buried oxide and the presence of which may be revealed by a decorated etch pit after treatment in hydrofluoric acid (HF)).

Because the active strained silicon layer is thin (on the order of 200 Å), it is important to be able to control accurately the quality of the layer and its final surface quality after removing the subsisting portion of the SiGe layer. The present invention now provides a method to accomplish this.

### SUMMARY OF THE INVENTION

The aim of the invention it to provide a solution which can facilitate removal or lifting-off by selective etching of a layer of silicon-germanium (SiGe) subsisting above a layer of strained silicon, and which is thus reliable while preserving the layer of strained silicon from excessive over-etching.

This aim is achieved by the present methods of providing a strained silicon layer on a substrate. These methods include providing an initial structure that includes an exposed silicon-germanium layer of formula Si₁₋ₓGeₓ where 0≦x≦1, the layer being disposed on a layer of strained silicon upon a substrate, oxidizing the exposed silicon-germanium layer to form a surface layer of silicon oxide and an enriched lower layer of silicon-germanium having a concentration of germanium that is higher than that of the initial exposed silicon-germanium layer to render the lower layer more susceptible to chemical etching, removing the silicon oxide layer, and then selectively chemically etching the silicon-germanium layer to provide an exposed layer of strained silicon layer on the substrate.

The oxidizing step is carried out in an oxidizing stream and at a temperature of about 800° C. for a sufficient time to form the silicon oxide surface layer without detrimentally affecting the strained silicon layer. The heating time depends upon the thickness of the silicon-germanium layer, e.g., when the exposed silicon-germanium layer has a thickness of around 100 Å and the oxidation step is conducted for 30 minutes or less.

The silicon oxide layer is preferably removed by a deoxidation step, e.g., one carried out in hydrofluoric acid. To minimize the thickness of the silicon oxide layer, the method further comprises, prior to the oxidation step, a step of thinning the exposed silicon-germanium layer. This layer thinning step can be carried out by selective etching, sacrificial oxidation or chemical-mechanical polishing. For example, when the exposed silicon-germanium layer has a germanium concentration of 20% (x=0.2), the thickness of the exposed silicon-germanium layer can be reduced to a value of about 100 Å without causing defects in the strained silicon layer. The selective etching can be carried out using an etching solution comprising a mixture of acetic acid, hydrogen peroxide and hydrofluoric acid, with a preferred solution including substantially equal amounts by weight of the acetic acid, hydrogen peroxide and hydrofluoric acid.

The initial structure can be provided by many different ways, but preferably is results from the well known SMART-CUT® layer transfer process that includes the steps of forming a layer of strained silicon on a layer of relaxed SiGe on a donor substrate; implanting atomic species in the relaxed SiGe layer to form a weakened zone therein; bonding the donor substrate to a receiving substrate; and detaching the donor substrate at the weakened zone to transfer the layer of strained silicon and layer of relaxed SiGe to the receiving substrate. The receiving substrate preferably includes a surface oxide layer that contacts the strained silicon layer when bonding. As is known in the art, the preferred atomic species to be implanted include hydrogen ions, helium ions or a co-implantation of hydrogen and helium ions.

### BRIEF DESCRIPTION OF THE DRAWING FIGURES

FIGS. 1A to 1E are diagrammatic sectional views showing the production of an sSOI type structure in accordance with an implementation of the invention;

FIG. 2 is a flowchart of steps carried out in FIGS. 1A to 1E;

FIG. 3 shows the variation in germanium concentration in a SiGe/sSi layer assembly after thinning and oxidation;

FIG. 4 shows the variation in germanium concentration in a SiGe/sSi layer assembly after transfer using SMART-CUT® technology.

### DETAILED DESCRIPTION OF THE PREFERRED EMBODIMENTS

The method of the present invention is generally applicable to any layer or remainder of a layer of silicon-germanium (Si₁₋ₓGeₓ where 0≦x≦1) subsisting above a layer of strained silicon and which is to be eliminated by selective etching. As a result, the present invention is of particular application in the fabrication of sSOI type wafers using the SMART-CUT® technique.

The layer of SiGe is intended to be lifted by selective chemical etching to expose the strained silicon layer on which it is disposed. This method comprises, prior to selective etching, a step of oxidation of the SiGe layer to form a surface layer of silicon oxide and a lower layer with a high and homogeneous concentration of germanium. The lower layer has a germanium concentration or content which is higher than that of the layer of SiGe prior to oxidation.

The step of oxidation of the SiGe layer allows a layer of silicon oxide containing very little germanium and a subjacent layer which is enriched in germanium to be formed. In this manner, a germanium-enriched layer is obtained very close to the strained silicon layer, which results in high selectivity between the germanium-enriched layer and the strained silicon layer. The selective etching efficacy is thus enhanced, with the result that there is no risk of over-etching for the strained silicon layer and furthermore, the etching period may be reduced. In the method of the invention, the SiGe layer may then be lifted readily, preserving the surface quality and the quality of the exposed strained silicon layer.

The oxidation step is preferably carried out in a stream of oxygen and at a temperature of about 800° C. to avoid excessive diffusion of germanium into the strained silicon layer.

In an aspect of the invention, the method further comprises, prior to selective etching and after the oxidation step, a step of deoxidation of the wafer in order to lift the silicon oxide layer. The deoxidation step may be carried out in hydrofluoric acid.

In a further aspect of the invention, the method further comprises, prior to the oxidation step, a step of thinning the SiGe layer. The step of thinning the SiGe layer may be carried out by etching or by chemical-mechanical polishing.

The thickness of the SiGe layer is reduced to a thickness sufficient to limit the strain caused by the germanium-enrichment step. In fact, if the layer of SiGe is too thick for the oxidation step, the strain caused by the accumulation of germanium between this zone and the strained silicon layer runs the risk of no longer being tolerated and causing the appearance of defects. For a layer of SiGe having a germanium content of 20% (Si_{0.9}Ge_{0/2}), the thickness of the SiGe layer is reduced to reach a thickness of about 100 Å. For layers of SiGe having higher germanium concentrations (for example 30% or 40% of Ge: x=0.3 to 0.4), the SiGe layer is thinned to values of less than 100 Å.

The present invention also provides a method of fabricating an sSOI type wafer, comprising:

forming a layer of strained silicon on a layer of relaxed SiGe of a donor substrate;

implanting gaseous species into the relaxed SiGe layer to form a zone of weakness therein;

bonding the strained silicon layer onto a receiver substrate; and

detaching the SiGe layer at the zone weakened by implantation by splitting;

the method being characterized in that it further comprises lifting the portion of the SiGe layer detached with the strained silicon layer by means of the removal methods described above.

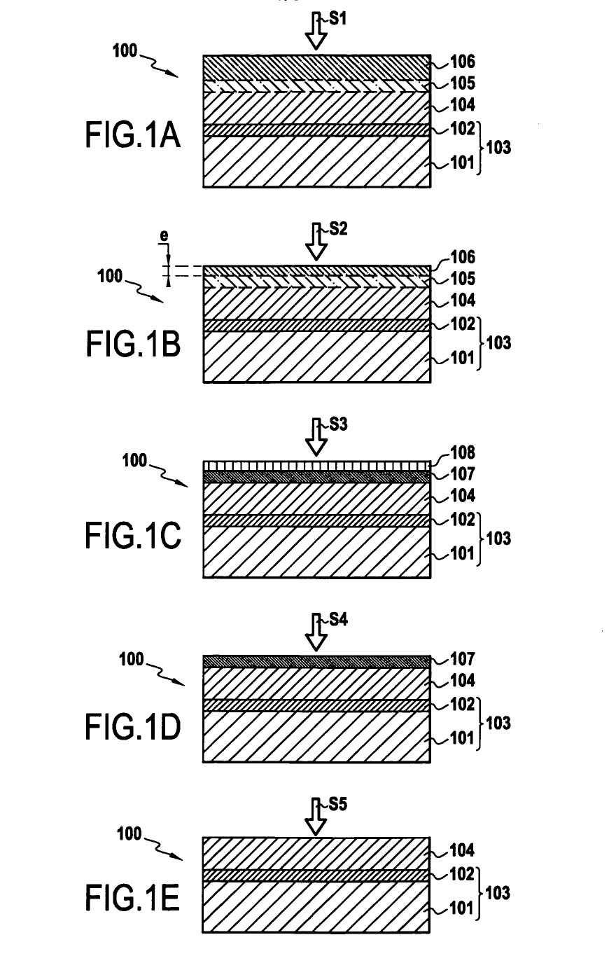

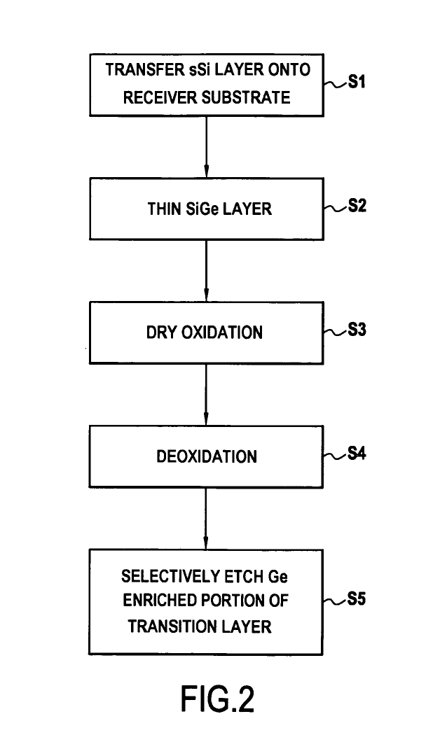

FIGS. 1A to 1E and 2 describe a method of producing a structure 100 of an sSOI type wafer in which the method of the invention for eliminating or lifting a SiGe layer is carried out. FIG. 1A illustrates the structure 100 obtained after transfer of a layer of strained silicon 104 from a donor substrate (not shown) to a receiver substrate 103, i.e. after:

implanting gaseous species (H, He, etc, alone or in combination) into the relaxed SiGe layer to form a zone of weakness therein;

bonding the strained silicon layer 104 to a receiver substrate 103;

detaching by splitting (thermally and/or mechanically) the SiGe layer at the zone weakened by implantation, and optionally

finishing by chemical etching, polishing/planarization and/or heat treatment.

The receiver substrate 103 comprises a support substrate 101, for example of silicon with a buried oxide layer 102 forming the insulating lager. Alternatively, or additionally, the oxide layer may be formed by deposition onto the strained layer.

It should be recalled that the strained silicon layer 104 is initially formed on a donor substrate formed by a silicon support substrate onto which a relaxed silicon-germanium (SiGe) layer has been formed by means of a SiGe buffer layer. This part of the production of an sSOI type structure is well known per se and is not described herein in any further detail.

As shown in FIG. 1A, after transfer of the strained silicon layer 104 onto the receiver substrate 103, a layer of SiGe 106 subsists that corresponds to the portion of the relaxed SiGe layer of the donor substrate that has been detached with the strained silicon layer (i.e., the portion of the SiGe layer located between the surface which undergoes implantation and the implantation zone). This SiGe layer must be eliminated to obtain the final structure of the sSOI wafer.

As explained above, during formation of the donor substrate and/or transfer of the strained silicon and SiGe layers, germanium diffuses into the strained silicon layer (e.g., a diffusion tail phenomena) so that the transition between the strained silicon layer 104 and the SiGe layer 106 (i.e., the transition between SiGe and sSi) is not abrupt (see FIG. 4). This interface between these two layers may be envisaged as a transition layer 105 which is at least partially buried in the strained silicon layer due to diffusion of elements of germanium into it. The concentration of germanium in the transition layer 105 is lower than that present in the SiGe layer 106. As an example, with a SiGe layer 106 having a germanium concentration of the order of 20% (Si_{0.8}Ge_{0.2} layer), the concentration of germanium in the transition layer 105 may vary from 20% to substantially 0 over a thickness in the range 50 Å to 100 Å.

Further, the selective etching of germanium over silicon loses its effectiveness at the transition layer 105. Furthermore, selective etching of the transition layer 105 becomes more difficult on approaching the strained silicon layer 104 as the concentration of germanium reduces (concentration gradient of Ge with increasing thickness of the transition layer).

Firstly, the SiGe layer 106 is thinned to a thickness e of about 100 Å (step S2, FIG. 1B). This thinning step can produce a thin SiGe layer which will be easier to treat (temperature reduction and reduction in oxidation period) throughout the remainder of the method of the invention. The SiGe layer 106 is preferably thinned to a value of about 100 Å since beyond that thickness, major defects may appear in the SiGe layer during subsequent processing steps. As is explained below, the germanium collects in a zone located between the SiGe layer and the strained silicon layer. As a result, the strain between this zone and the strained silicon is augmented which, at a thickness of the SiGe layer of more than 100 Å, the structure can no longer tolerate the strain and causes the appearance of major defects in the SiGe layer. These defects may even extend into the strained silicon layer. It should be noted that this thickness of 100 Å is particularly suitable for SiGe layers with a Ge concentration of the order of 20%. For higher concentrations (30% or more), this thickness will be different (i.e. it must be thinner).

The SiGe layer 106 may be thinned, for example, by polishing or chemical-mechanical polishing. Methods of polishing or chemical-mechanical polishing relaxed SiGe layers are described in PCT documents PCT/EP2004/006186 and PCT/EP2004/011439, the contents of which are hereby incorporated by reference. It will be recalled that polishing or chemical-mechanical polishing may be carried out with a relatively hard fabric (for example a fabric having a compressibility of between 2% and 15%) associated with a polishing solution containing an agent (for example NH₄OH) which can chemically attack the surface of the layer and abrasive particles (for example silica particles with a diameter of 70 nanometers (nm) to 1000 nm with a silica content of more than 20%) which can mechanically attack the surface.

The SiGe layer 106 may also be thinned by etching. Further, since the etching time is deliberately limited to interrupt etching before it reaches the strained silicon layer and not cause the formation of HF defects therein, it is possible to use an etching solution having a faster and/or more uniform etching rate (i.e., with no HF defects). As an example, an acetic acid solution (CH₃COOH/H₂O₂/HF solution may be used in a 1/1/1 ratio, which is more aggressive than the solution normally used which has a 10/10/1 ratio. Furthermore, this solution (CH₃COOH/H₂O₂/HF, 1/1/1) may comprise additives such as sulfuric acid to make it more aggressive.

Thinning may also be carried out by “wet” oxidation (oxidation carried out in H₂O) followed by deoxidation (sacrificial oxidation).

The SiGe layer 106 is preferably thinned by etching. In fact, etching can keep the layer more uniform than polishing and preserves uniformity of the SiGe layer prior to oxidation. This is important because a non uniform SiGe layer results in a Ge-enriched layer which is also non uniform and thus runs the risk of over-etching the SiGe layer at thinner regions.

Sacrificial oxidation of the SiGe layer 106 is then carried out (i.e. oxidation followed by deoxidation). The conditions for sacrificial oxidation are selected so that only SiO₂ is formed to enrich the subjacent transition layer 105 in germanium. The sacrificial oxidation initially comprises a step of oxidation of the SiGe layer 106 (step S3). Oxidation is preferably of the “dry” type, i.e. carried out in a stream of oxygen to allow the accumulation of germanium, which then is discharged from the oxide by segregation to thereby enrich the lower portion of the SiGe layer in germanium, namely essentially the transition layer 105. Furthermore, oxidation is carried out at low temperature, i.e., at about 800° C., to prevent germanium from diffusing into the strained silicon layer and eliminating the abrupt transition between the germanium and silicon.

In known manner, the SiGe layer 106 may be oxidized by placing the wafers in a quartz tube inside which a stream of oxygen moves while controlling the temperature inside the tube using heating bodies disposed around the tube, and probes for heat measurement in the tube. The oxidation period is adjusted to consume more silicon atoms present in the SiGe layer. As an example, for a SiGe layer 100 Å thick, the oxidation period is of the order of 30 minutes. Clearly, the oxidation period is a function of the thickness of the SiGe layer. The oxidation period may thus be reduced by further reducing the thickness of the SiGe layer prior to oxidation, for example to a value of the order of 50 Å. However, the thickness of the SiGe layer can only be reduced to the extent that the uniformity of the SiGe layer is not deteriorated. As explained above, if the uniformity of the SiGe layer is not preserved prior to oxidation, a non uniform germanium-enriched layer is obtained, running the risk of over-etching and the appearance of defects.

During oxidation of the SiGe layer 106 (i.e. in a stream of O₂ at about 800° C.), the oxygen atoms present in the SiGe encounter silicon atoms to form silicon oxide:
Si+O₂→SiO₂
The oxide layer starts to grow from the surface of the SiGe layer and extends progressively into the thickness of the SiGe layer by diffusion of oxygen through the oxide during formation.

In this manner and as shown in FIG. 1C, the SiGe layer 106 oxidizes into a SiO₂ layer 108, which causes segregation of germanium into a lower zone of the layer at the transition layer 105. This segregation also results in the formation of a layer 107 of germanium or SiGe with a high concentration of germanium (which may reach about 80%). At this stage of the method, the strained silicon layer 104 is separated from the SiO₂ layer 108 by the germanium-enriched layer 107.

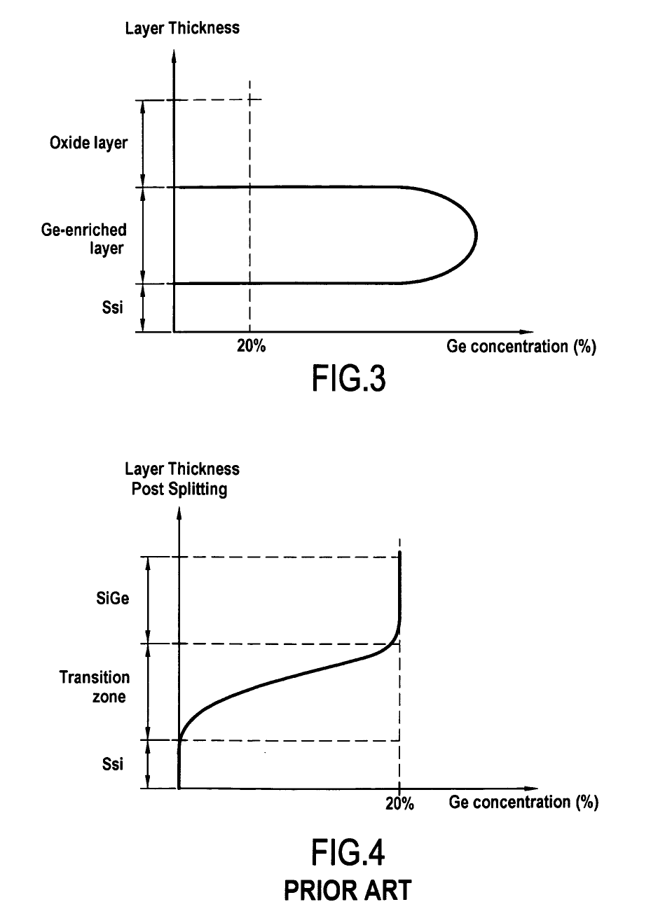

FIG. 3 shows the germanium distribution after oxidation of the SiGe layer 106. It will be observed that the transition between the zone containing germanium, i.e. the germanium-enriched layer, and the strained silicon layer has now become abrupt compared with this same transition prior to oxidation as shown in FIG. 4. The germanium-enriched layer also has a germanium concentration which is much higher than that of the SiGe layer prior to oxidation (namely 20% in the example under consideration).

The SiO₂ layer 108 is then eliminated by deoxidation (step S4, FIG. 1D) in hydrofluoric acid (HF), for example. Sacrificial oxidation methods are well known to the skilled person who will know how to adjust the temperature conditions (to avoid too much diffusion of Ge into the strained silicon layer), the treatment period, and the oxygen concentration to carry out sacrificial oxidation to enrich the germanium transition layer 105 as best as possible.

After deoxidation, the surface of the structure 100 only has the layer 107 which is enriched in germanium. This layer may thus be removed with greater ease by selective etching (step S5). Increasing the concentration of germanium in the interface zone between the layer of SiGe and the layer of strained silicon allows better etching selectivity of SiGe over strained silicon. In particular, over-etching of the strained silicon layer may thus be avoided since the selective etching no longer needs to be prolonged to compensate for the low concentration of germanium normally encountered in this zone.

After lifting the germanium-enriched layer, a very small surface concentration in the remaining layer may be tolerated; it may be of the order of about 0.01%. This residual quantity of germanium does not affect the final quality of the layer for two reasons:

the heat treatments which follow (reinforcing the bonding interface, defect repair, 1000° C. 2 h) allow the remaining Ge to diffuse throughout the thickness of the layer and thus limit its mean concentration;

below a threshold (5×10¹⁰ atoms/cm³), the remaining atoms of Ge are considered to be impurities at an acceptable level.

Selective etching of the layer 107 (step S5) may be carried out with an etching solution constituted, for example, by a well known mixture of acetic acid (CH₃COOH) (HAc), hydrogen peroxide (H₂O₂) and hydrofluoric acid (HF). This selective etching may be carried out by immersing wafers in an etching solution or by using single wafer wet chemical treatment in which selective etching is carried out by dispensing the etching solution directly onto the rotating wafer. Typically, the etching depth is controlled as a function of the duration of contact between the etching solution and the layer to be etched. For a given etching solution, the etching rate of a SiGe layer is known. As a result, control of the etching depth, which must correspond to the depth of the layer 107 to be eliminated, can be controlled as a function of the duration of the contact between the layer 107 and the etching solution. Furthermore, some etching equipment has optical systems which allow “in situ” measurement of the etched thickness and, as a result, allow etching to be interrupted when the desired thickness is reached.

After the selective etching step, the final structure of the sSOI wafer is obtained, namely the layer of strained silicon 104 on the substrate 103 (FIG. 1E).

What is claimed is:

1. A method of providing a strained silicon layer on a substrate, which comprises providing a structure that includes an exposed silicon-germanium layer of formula Si₁₋ₓGeₓ where 0≦x≦1, the layer being disposed on a layer of strained silicon upon a substrate, oxidizing the exposed silicon-germanium layer to form a surface layer of silicon oxide and an enriched lower layer of silicon-germanium having a concentration of germanium that is higher than that of the initial exposed silicon-germanium layer to render the lower layer more susceptible to chemical etching, removing the silicon oxide layer, and then selectively chemically etching the silicon-germanium layer to provide an exposed layer of strained silicon layer on the substrate.

2. The method according to claim 1, wherein the oxidizing step is carried out in an oxidizing stream and at a temperature of about 800° C. for a sufficient time to form the silicon oxide surface layer without detrimentally affecting the strained silicon layer.

3. The method according to claim 2, wherein the exposed silicon-germanium layer has a thickness of around 100 Å and the oxidation step is conducted for 30 minutes or less.

4. The method according to claim 1, wherein the silicon oxide is removed by a deoxidation step.

5. The method according to claim 4, wherein the deoxidation step is carried out in hydrofluoric acid.

6. The method according to claim 1, which further comprises, prior to the oxidation step, a step of thinning the exposed silicon-germanium layer.

7. The method according to claim 6, wherein the layer thinning step is carried out by selective etching, sacrificial oxidation or chemical-mechanical polishing.

8. The method according to claim 6, wherein the exposed silicon-germanium layer has a germanium concentration of 20% (x=0.2) and thickness of the exposed silicon-germanium layer is reduced to a value of at least about 100 Å.

9. The method according to claim 6, wherein the exposed silicon-germanium layer has a germanium concentration of 30 to 40% (x=0.3 to 0.4) and thickness of the exposed silicon-germanium layer is reduced to a value of less than 100 Å.

10. The method according to claim 1, wherein the selective etching is carried out using an etching solution comprising a mixture of acetic acid, hydrogen peroxide and hydrofluoric acid.

11. The method according to claim 10, wherein the acetic acid, hydrogen peroxide and hydrofluoric acid are present in substantially equal amounts by weight in the solution.

12. The method according to claim 1, wherein the structure is provided by
forming a layer of strained silicon on a layer of relaxed SiGe on a donor substrate;
implanting atomic species in the relaxed SiGe layer to form a weakened zone therein;
bonding the donor substrate to a receiving substrate; and
detaching the donor substrate at the weakened zone to transfer the layer of strained silicon and layer of relaxed SiGe to the receiving substrate.

13. The method of claim 12, wherein the receiving substrate include a surface oxide layer that contacts the strained silicon layer when bonding.

14. The method of claim 12, wherein the atomic species to be implanted include hydrogen ions, helium ions or a co-implantation of hydrogen and helium ions.
